(19) United States
(12) Patent Application Publication
(10) Pub. No.: US 2025/0029934 A1
(43) Pub. Date: Jan. 23, 2025

(54) LIGHT-EMITTING DIODE, LIGHT-EMITTING DIODE CHIPLET AND LIGHT-EMITTING DEVICE

(71) Applicant: XIAMEN SAN'AN OPTOELECTRONICS CO., LTD., Xiamen (CN)

(72) Inventors: Gong CHEN, Xiamen (CN); Yashu ZANG, Xiamen (CN); Chunhsien LEE, Xiamen (CN); Weichun TSENG, Xiamen (CN); Chung-Ying CHANG, Xiamen (CN); Jiming CAI, Xiamen (CN); Shao-hua HUANG, Xiamen (CN); Chunlan HE, Xiamen (CN); Ziyan PAN, Xiamen (CN)

(21) Appl. No.: 18/772,126

(22) Filed: Jul. 13, 2024

(30) Foreign Application Priority Data
Jul. 18, 2023 (CN) 2023108799045

(51) Int. Cl. H01L 23/544; H01L 25/075; H01L 33/44

(52) U.S. Cl. CPC H01L 23/544; H01L 25/0753; H01L 33/44; H01L 2223/5446

(57) ABSTRACT

A light-emitting diode includes: a substrate, an epitaxial layer and a protective layer; the epitaxial layer is disposed on the substrate and includes a first semiconductor layer, an active layer, and a second semiconductor layer stacked sequentially in that order; the protective layer covers the epitaxial layer; the epitaxial layer is divided into chiplets, each chiplet includes transverse and longitudinal sidewalls intersecting in transverse and longitudinal directions, dicing channels are defined between adjacent chiplets, the dicing channels include transverse and longitudinal dicing channels extending respectively in the transverse and longitudinal directions, the protective layer covers the dicing channels and chiplet sidewalls, a patterned structure is disposed on the protective layer in an intersecting area of the transverse and the longitudinal dicing channels, and includes a groove extending toward the substrate. The light-emitting diode effectively prevents the crack extension, avoids edge and corner chipping during dicing, thus ensuring element quality.

### CROSS-REFERENCE TO RELATED APPLICATION

This application claims priority to Chinese Patent Application No. 202310879904.5, filed Jul. 18, 2023, which is herein incorporated by reference in its entirety.

### TECHNICAL FIELD

The disclosure relates to the field of semiconductor manufacturing technology, and more particularly to a light-emitting diode (LED), a LED chiplet and a light-emitting device.

### BACKGROUND

In a process of LED chip manufacturing, dicing a LED wafer into individual LED chiplets is a crucial step. Currently, a primary method for splitting the LED chiplets is through laser stealth dicing. During the dicing process, a laser sequentially scans along transverse dicing channels and longitudinal dicing channels to form explosion points within substrates of the chiplets. Subsequently, a dicing blade cuts a photo voltaic (PV) protective layer on the upper surfaces of the chiplets, so as to split the LED wafer into the individual chiplets completely.

However, due to the brittleness of the PV protective layer on the upper surfaces of the chiplets, the dicing blade needs to make contact with the PV protective layer twice in an intersecting area of the dicing channels, which can easily cause the PV protective layer to form cracks, leading to edge and corner chipping. When these cracks further extend into an epitaxial structure of the chiplet, they affect the performance of the LED chiplet and the quality reliability of elements.

Therefore, there is a need to provide an improved technical solution to address the shortcomings of the related art mentioned above.

### SUMMARY

In view of the defects and shortcomings in the LED chiplet dicing process of the aforementioned related art, an objective of the disclosure is to provide a LED, a LED chiplet, and a light-emitting device, the objective is achieved by providing a patterned structure with a groove in an intersecting area of dicing channels of LED chiplets, when edge and corner chipping occurs due to repeated contact between the dicing blade and the protective layer, the patterned structure effectively prevents the cracks from further extending into the epitaxial layer, ensuring the quality reliability of the elements.

In the first aspect, the disclosure provides a LED, including:
a substrate, having a upper surface and a lower surface disposed opposite to the upper surface;
an epitaxial layer, disposed on the upper surface of the substrate, where the epitaxial layer includes a first semiconductor layer, an active layer, and a second semiconductor layer which are sequentially stacked in that order; and
a protective layer, covering the epitaxial layer;
where the epitaxial layer is divided into multiple chiplets, each chiplet includes sidewalls intersecting in transverse and longitudinal directions, and the sidewalls of each chiplet include transverse sidewalls and longitudinal sidewalls; a dicing channel is defined between every adjacent two of the chiplets; the dicing channels of the chiplets include transverse dicing channels and longitudinal dicing channels extending respectively along the transverse and longitudinal directions; the protective layer covers the dicing channels and the sidewalls of each chiplet; the protective layer is provided with a patterned structure in each intersecting area of the transverse and longitudinal dicing channels, and the patterned structure includes a groove extending towards the substrate.

In the second surface, the disclosure provides a LED chiplet obtained by dicing the LED according to the technical solution described herein.

In the third surface, the disclosure provides a light-emitting device, including a substrate and a light-emitting element fixed on the substrate, and the light-emitting element includes the LED chiplet as described in the technical solution described herein.

Compared to the related art, the technical solutions provided by the disclosure offer the following beneficial effects.

In the technical solutions of the disclosure, the patterned structure is provided in the intersecting area of the dicing channels of the adjacent chiplets, this isolates the repeated contact points in the intersecting area of the dicing channels from the epitaxial structures at the corners of the adjacent four chiplets, breaking the connection between the protective layer on the epitaxial structures and the repeated contact points of the dicing blade and the protective layer on the upper surfaces of the chiplets. The patterned structure restricts the cracks generated at the intersecting point within the patterned structure itself, reducing the probability of stress cracking caused by repeated contact between the dicing blade and the protective layer. Even if the cracks are generated, the patterned structure can effectively prevent the cracks from continuing to extend along the protective layer. The patterned structure in the intersecting area can simultaneously protect the adjacent four chiplets. Since the patterned structure includes the groove extending towards the substrate, the dicing intersecting point of the dicing blade in the intersecting area of the dicing channels can be formed within the groove, rather than on the protective layer, directly avoiding the generation of the cracks as well as edge and corner chipping, or blocking the development of the cracks by the groove extending to the inside of the protective layer, enhancing the reliability of the chiplet. At the same time, the patterned structure with the groove is arranged in the intersecting area of the dicing channels of the chiplets, most of the protective layer can be retained, ensuring the protective effect of the protective layer on the LED and further improving the reliability of the chiplets.

Additionally, the patterned structure is configured as a dicing mark that can be identified by dicing equipment such as a laser splitting machine and a dicing machine, facilitating capture by the machine. When different chiplet patterns are designed on the same wafer, the dicing precision alignment can be achieved by identifying and capturing the dicing marks.

Furthermore, the LED provided by the disclosure has the excellent light-emitting effect, effectively avoiding the structural loss with large height difference caused by etching and hollowing out the patterned structure, resulting in a more uniform thickness of the encapsulant in later stages, reducing the loss of light-emitting efficiency due to light reflection at the edges of the light-emitting area, improving light-emitting uniformity, and ensuring process stability and chiplet quality.

### BRIEF DESCRIPTION OF DRAWINGS

FIG. 1 illustrates a schematic diagram of laser stealth dicing in the related art.

FIG. 2 illustrates a schematic diagram of a contact path between a dicing blade and dicing channels in the related art.

FIG. 3 illustrates an enlarged view of an area P0 in FIG. 2.

FIG. 4 illustrates a top view of a LED according to an embodiment 1 of the disclosure.

FIG. 5 illustrates an enlarged view of an area P1 in FIG. 4.

FIG. 6 illustrates a cross-sectional view of the LED along a line A-A in FIG. 4 according to an embodiment of the disclosure.

FIG. 7 illustrates a cross-sectional view of the LED along a line A-A in FIG. 4 according to another embodiment of the disclosure.

FIG. 8 illustrates a top view of a LED according to an embodiment 2 of the disclosure.

FIG. 9 illustrates an enlarged view of an area P2 in FIG. 8.

FIG. 10 illustrates a cross-sectional view of the LED along a line B-B in FIG. 8.

FIG. 11 illustrates a schematic light-emitting diagram of the LED according to the embodiment 1 of the present disclosure.

FIG. 12 illustrates a schematic light-emitting diagram of the LED according to the embodiment 2 of the present disclosure.

FIG. 13 illustrates a top view of a LED according to an embodiment 3 of the disclosure.

FIG. 14 illustrates an enlarged view of an area P3 in FIG. 13.

FIG. 15 illustrates a cross-sectional view of the LED along a line C-C in FIG. 13.

FIG. 16 illustrates a top view of a LED according to an embodiment 4 of the disclosure.

FIG. 17 illustrates an enlarged view of an area P4 in FIG. 16.

FIG. 18 illustrates a cross-sectional view of the LED along a line D-D in FIG. 16.

FIG. 19 illustrates a schematic structural diagram of a LED chiplet according to an embodiment 6 of the disclosure.

FIG. 20 illustrates a schematic structural diagram of a light-emitting device according to an embodiment 7 of the disclosure.

FIG. 21 illustrates a top view of a chiplet obtained by dicing the LED in FIG. 4 according to the embodiment 1 of the disclosure.

FIG. 22 illustrates a top view of a chiplet obtained by dicing the LED in FIG. 8 according to the embodiment 2 of the disclosure.

FIG. 23 illustrates a top view of a chiplet obtained by dicing the LED in FIG. 13 according to the embodiment 3 of the disclosure.

FIG. 24 illustrates a top view of a chiplet obtained by dicing the LED in FIG. 16 according to the embodiment 4 of the disclosure

Description of reference signs are as follows:
110: substrate; 120: epitaxial layer; 121: first semiconductor layer; 122: active layer; 123: second semiconductor layer; 130: protective layer; 140: first electrode; 150: second electrode;
200: dicing channel; 210: overlapping area;
300: groove;
400, 500, 600, 700: patterned structure;
410: cross-shaped notch;
510: island body; 520: gap;
610: central notch; 620: strip groove;
710: cross-shaped slot; 720: L-shaped slot;
10: circuit substrate; 20: light-emitting element.

### DETAILED DESCRIPTION OF EMBODIMENTS

The following specific embodiments will illustrate implementation methods of the disclosure, and those skilled in the art can easily understand the other advantages and effects of the disclosure from the content disclosed in the specification. The disclosure can also be implemented or applied through different specific implementation methods, and the details in the specification can be modified or amended based on different perspectives and applications without deviating from the spirit of the disclosure.

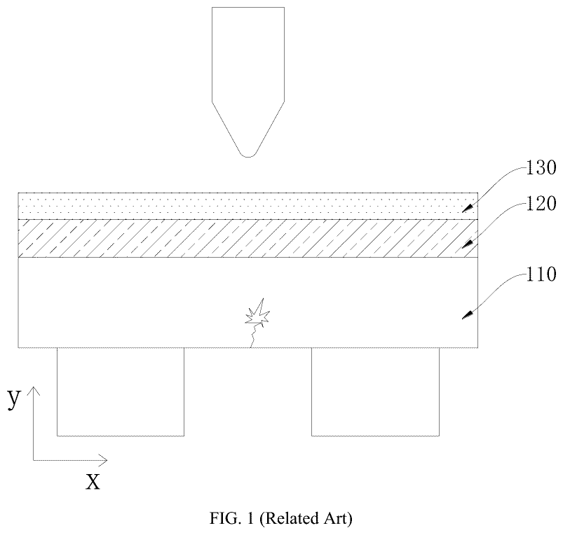

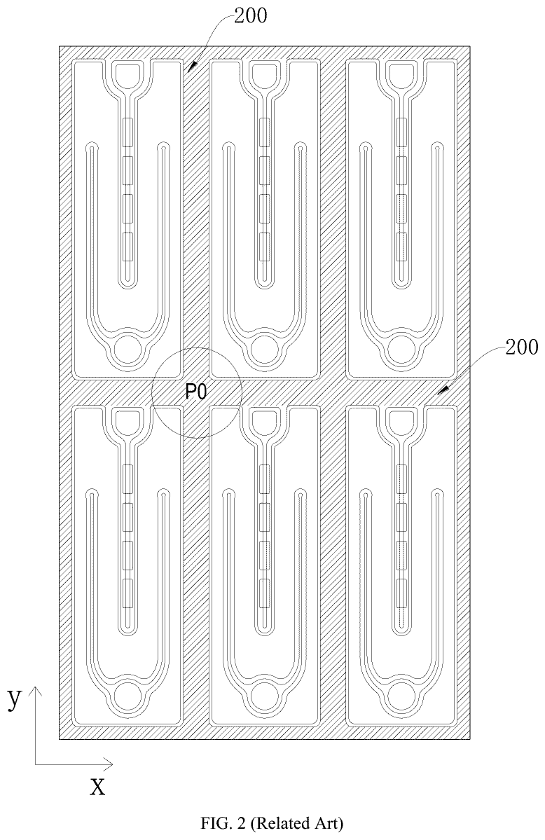

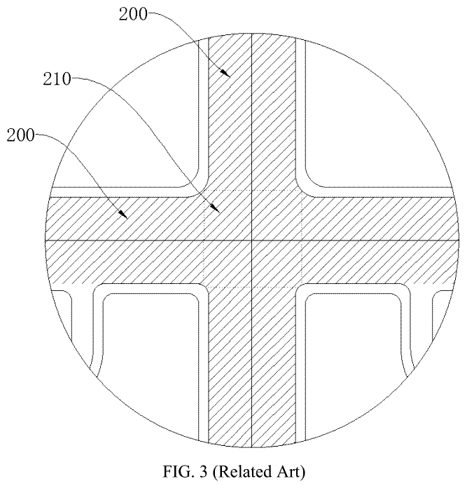

As illustrated in FIG. 1, it illustrates a method of dicing LED chiplets by laser stealth dicing in the related art. Firstly, the laser is incident at a certain depth on the substrate to generate an explosion point. To reduce the damage to the epitaxial layer caused by the laser, the explosion point is placed as far away from the epitaxial layer as possible, leading to a lower surface of the substrate, which faces away from the epitaxial layer, cracking under the explosion energy first. Subsequently, a dicing process is performed, conducting a frontal dicing on the chiplets to ensure their complete separation. Each chiplet has two sides, and between adjacent chiplets, there are dicing channels intersecting in an x-direction and a y-direction. As illustrated in FIGS. 2 and 3, a dicing blade is in contact with the adjacent chiplets twice at their boundary, forming an intersecting point of dicing lines. Due to the in brittleness of the protective layer, it is very easy for the protective layer to crack, leading to the generation of cracks as well as edge and corner chipping. When these cracks further extend into the epitaxial structure of the chiplets, they will impact the performance of the LED chiplets and the quality reliability of the light-emitting device.

To address the above defects, the disclosure provides a LED, including:
a substrate, having a upper surface and a lower surface that are arranged oppositely;
an epitaxial layer, disposed on the upper surface of the substrate, where the epitaxial layer includes a first semiconductor layer, an active layer, and a second semiconductor layer which are sequentially stacked in that order; and
a protective layer, covering the epitaxial layer;
the epitaxial layer is divided into multiple chiplets, each chiplet includes transverse and longitudinal sidewalls intersecting in transverse and longitudinal directions, a dicing channel is defined between every adjacent two chiplets, the dicing channels of the chiplets include transverse dicing channels and longitudinal dicing channels extending respectively along the transverse and longitudinal directions, the protective layer covers the dicing channels and the sidewalls of each chiplet, the protective layer is provided with a patterned structure in each intersecting area of the transverse and longitudinal dicing channels, and the patterned structure includes a groove extending towards the substrate.

By adopting the above technical solution, the patterned structure is provided in each intersecting area of the dicing channels, the patterned structure isolates the repeated contact points in the intersecting area of the dicing channels from the epitaxial structure, breaking the connection between the epitaxial structure and the repeated contact point of the dicing blade and the protective layer on the upper surface of the chiplet. This reduces the probability of stress cracking caused by repeated contact between the dicing blade and the protective layer. Even if the cracks are generated, the patterned structure can effectively prevent the cracks from continuing to extend along the protective layer. Since the patterned structure includes the groove extending towards the substrate, the dicing intersecting point of the dicing blade in the intersecting area of the dicing channels can also be formed within the groove, rather than on the protective layer, directly avoiding the generation of cracks as well as edge and corner chipping, or blocking the development of the cracks by the groove extending to the inside of the protective layer.

The disclosure also provides a LED, including:
a substrate, having a upper surface and a lower surface that are arranged oppositely;
an epitaxial layer, disposed on the upper surface of the substrate, where the epitaxial layer includes a first semiconductor layer, an active layer, and a second semiconductor layer which are sequentially stacked in that order; and
a protective layer, covering the epitaxial layer;
the epitaxial layer is divided into multiple chiplets, each chiplet includes transverse and longitudinal sidewalls intersecting in transverse and longitudinal directions, a dicing channel is defined between every adjacent two chiplets, the dicing channels of the chiplets include transverse dicing channels and longitudinal dicing channels extending respectively along the transverse and longitudinal directions, and the protective layer covers the dicing channels and the sidewalls of each chiplet; in each intersecting area of the transverse and longitudinal dicing channels, the protective layer is provided with a groove extending towards the substrate; and an island body is disposed in the groove, and a gap is defined between the island body and an edge of the groove.

By adopting the above technical solution, when the dicing blade repeatedly contacts the protective layer, even if cracking occurs at the intersecting point, a distance that the cracks extend in any direction is limited to the interior of the island body, the cracks are unable to extend to the epitaxial structure to adversely affect the element performance. Providing the island body within the groove also helps to reduce the overall coverage area of the groove, avoiding the structural loss with large height difference caused by completely etching and hollowing out the groove. During a subsequent encapsulation process, a thickness of the encapsulant is more uniform, allowing the edge of the encapsulant to form a basically flat light-emitting surface, reducing the loss of light-emitting efficiency due to light reflection at the edges of the light-emitting area, improving the light-emitting uniformity and the consistency of the light-emitting direction, and thus stabilizing the chiplet quality.

The disclosure also provides a LED chiplet obtained by dicing the LED as described in the aforementioned technical solution.

The disclosure also provides a light-emitting device, including a substrate and a light-emitting element fixed on the substrate, and the light-emitting element includes the LED chiplet as described in the aforementioned technical solution.

A detailed description now is given by the following embodiments. For the convenience of description, a coordinate system is defined as follows, as illustrated in FIGS. 4-6, the x-axis and y-axis respectively represent extension directions of two intersecting dicing channels, the extension directions of the two intersecting dicing channels are perpendicular to each other, the z-axis represents a depth direction of the LED, and the z-axis is perpendicular to a plane where the x-axis and y-axis lie.

### Embodiment 1

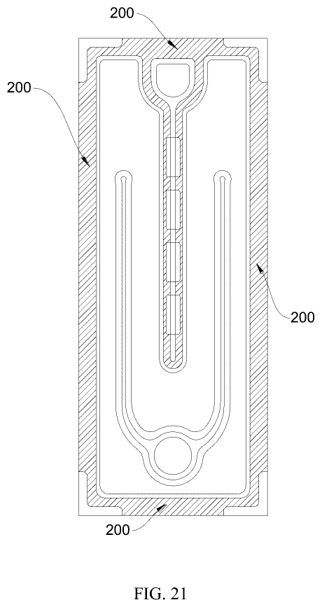

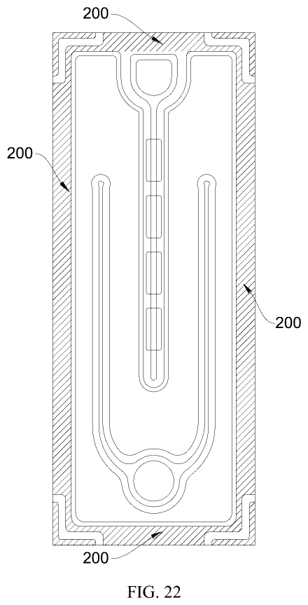

The embodiment provides a LED, as illustrated in FIGS. 4 to 7, the LED includes: a substrate 110, an epitaxial layer 120 and a protective layer 130. The substrate 110 has a upper surface and a lower surface which are arranged oppositely. The epitaxial layer 120 is disposed on the substrate 110, and the epitaxial layer 120 includes a first semiconductor layer 121, an active layer 122, and a second semiconductor layer 123 which are stacked sequentially in that order. The protective layer 130 covers the epitaxial layer 120. The epitaxial layer 120 is divided into multiple chiplets, and each chiplet includes sidewalls intersecting in transverse and longitudinal directions, and the sidewalls of each chiplet include transverse sidewalls and longitudinal sidewalls. A dicing channel 200 is defined between every adjacent two chiplets. The dicing channels 200 of the chiplets include transverse dicing channels and longitudinal dicing channels extending respectively along the transverse and longitudinal directions. As illustrated in FIG. 21, each chiplet is provided with multiple dicing channels 200, for example, two transverse dicing channels and two longitudinal dicing channels extending respectively along the transverse and longitudinal directions. The protective layer 130 covers the dicing channels 200 and the sidewalls of each chiplet. In each intersecting area of the transverse and longitudinal dicing channels, the protective layer 130 is provided with a patterned structure 400. When dicing the chiplets from the upper surface, the patterned structure 400 isolates the repeated contact points in the intersecting area of the dicing channels from the epitaxial structure (i.e., the epitaxial layer) of the chiplet, breaking the connection between the epitaxial structure and the repeated contact points of the dicing blade and the protective layer 130 of the chiplet. The patterned structure 400 reduces the probability of stress cracking caused by repeated contact between the dicing blade and the protective layer 130 with brittleness. Even if the cracks are generated, the patterned structure 400 can effectively prevent the cracks from continuing to extend along the protective layer 130 to the epitaxial structure. The patterned structure 400 includes a groove 300 extending towards the substrate 110. Therefore, the dicing intersecting point of the dicing blade in the intersecting area of the dicing channels can be formed within the groove 300, rather than on the protective layer 130, directly avoiding the generation of cracks as well as edge and corner chipping, or blocking the development of cracks by the groove 300 extending to the inside of the protective layer 130.

In an alternative embodiment, the aforementioned chiplet further includes an electrode structure. The electrode structure includes a first electrode 140 and a second electrode 150, which are electrically connected to the first semiconductor layer 121 and the second semiconductor layer 123, respectively. The material of the electrode structure is selected from at least one selected from the group consisting of gold, silver, copper, aluminum, chromium, nickel, titanium, and platinum, or from at least one of alloys and stacked layers composed of the aforementioned materials.

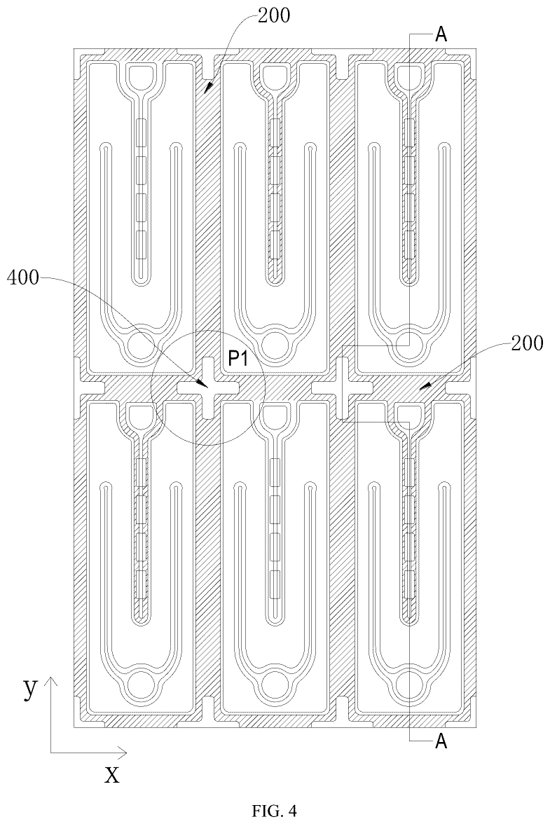

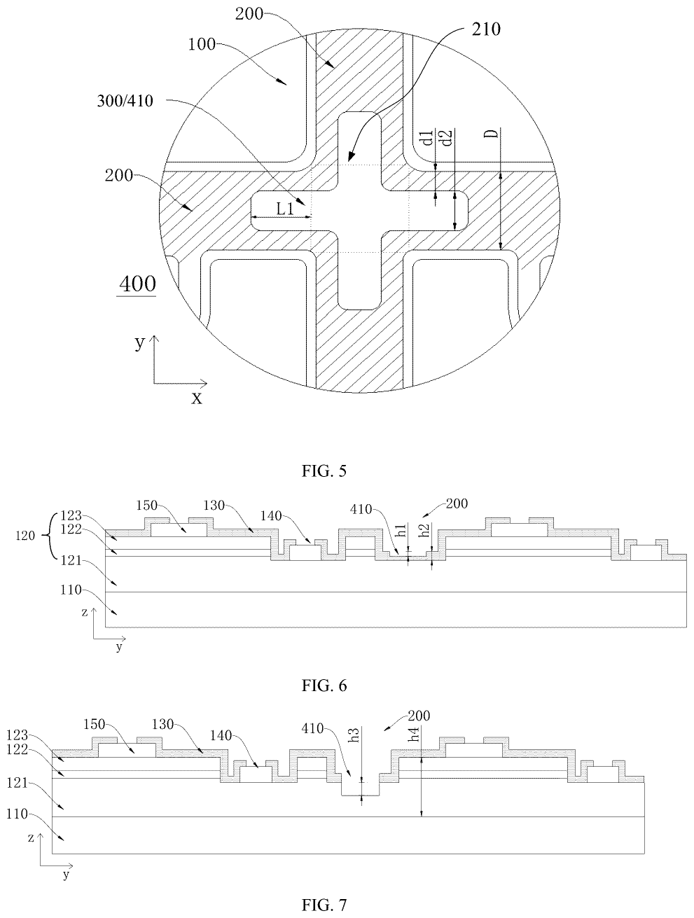

In the embodiment, as illustrated in FIGS. 4 and 5, the patterned structure 400 includes a cross-shaped structure intersecting in the transverse and longitudinal directions, and each branch of the cross-shaped structure extends to the corresponding dicing channel 200 between the adjacent chiplets. Defining a rectangular region where the transverse dicing channel and the longitudinal dicing channel overlap as an overlapping area 210, that is, each branch of the cross-shaped structure extends beyond the overlapping area 210 of the dicing channels 200. It can be understood that if the patterned structure 400 is limited only to the internal area of the overlapping area 210 of the dicing channels 200, there is still a probability and uncertainty of cracks extending along the protective layer 130 to all sides during the dicing, especially making it difficult to effectively protect the corners of the chiplets. Extending the four branches of the patterned structure 400 further into the dicing channels 200 for a certain distance is equivalent to removing more of the protective layer 130 along the extension direction of each dicing channel 200, i.e., performing a larger area hollowing treatment on the dicing channels 200. On one hand, the area of the remaining protective layer 130 can effectively lower the chance of the protective layer 130 creaking during the dicing. On the other hand, the groove 300 extending in all directions plays a role in blocking the extension of the cracks to the corners of the chiplets. Even if the cracks are generated at the intersecting point of the boundaries between the dicing channels 200 and the protective layer 130, it is difficult for the cracks to continue to extend along the protective layer 130, the edge and corner chipping can be avoided.

In an alternative embodiment, as illustrated in FIGS. 4 and 5, defining that each branch of the cross-shaped structure has a length in the extension direction and a width in a direction intersecting the extension direction (i.e., perpendicular to the extension direction), an extension distance L1 of each branch outside the overlapping area 210 is greater than or equal to 0.1 μm, and less than or equal to half a sidewall length of the corresponding chiplet in the length direction. The extension distance L1 is at least 0.1 μm to form a certain dislocation with the corners of the chiplets at the starting points where the cracks are generated. The extension distance L1 is at most half the sidewall length of the corresponding chiplet, leaving some of the protective layer 130 in the x-axis and y-axis dicing channels 200 (i.e., transverse and longitudinal dicing channels 200), ensuring good protection of the side surfaces of the chiplets. In an alternative embodiment, as illustrated in FIGS. 4 and 5, the extension distance L1 of each branch outside the overlapping area 210 is greater than or equal to 3 μm, and less than or equal to one quarter the sidewall length of the corresponding chiplet in the length direction. This size limitation optimizes the parameter selection range between the protection effect on the side surfaces of the chiplets and the location where cracks are generated. Compared with the aforementioned embodiment, setting the extension distance L1 to at least 3 μm further increases the dislocation between the starting points where the cracks are generated and the corners of the chiplets, making the contact points between the dicing blade and the boundaries of the protective layer 130 as far away as possible from the four corners of the chiplets. At the same time, the extension distance L1 is less than or equal to one quarter the sidewall length of the corresponding chiplet in the length direction, leaving sufficient areas of the protective layer 130 in the transverse and longitudinal dicing channels 200, providing better protection for the side surfaces of the chiplets.

In some embodiments, the lengths of the four branches of the cross-shaped structure are either the same or different. FIGS. 4, 8, 13, and 16 illustrate scenarios where the lengths of the four branches are the same. It can be understood that the lengths of the four branches of the cross-shaped structure can be adjusted based on the size and aspect ratio of the chiplet itself, balancing and optimizing the protective effect on both the length and width sides of the chiplet.

In some embodiments, a depth of the groove 300 is greater than or equal to 0.01 μm. This groove depth is specified as the minimum depth capable of isolating the cracks generated at the intersecting point.

In the above embodiments, the groove 300 extends in the depth direction into the protective layer 130, and at most penetrates through the protective layer 130. When forming the dicing channels 200, the entire epitaxial layer 120 at the dicing channels 200 is etched away. In the depth direction, only the substrate 110 and the protective layer 130 retain at the dicing channels 200. By forming the patterned structure on the protective layer 130, even if the cracks are generated in the protective layer 130, they cannot extend downward to the epitaxial layer 120, effectively preventing edge and corner chipping. The patterned structure can also prevent solder paste from entering during die bonding and causing electrical leakage. It can be understood that the aforementioned embodiments are also applicable when only a part of the epitaxial layer 120 at the dicing channels 200 is etched away when forming the dicing channels 200.

In the above embodiments, as illustrated in FIGS. 6 and 7, a part of the epitaxial layer 120 is retained when forming the dicing channels 200. The groove 300 penetrates through the protective layer 130 in the depth direction and extends below the upper surface of the epitaxial layer 120. The protective layer 130 at the patterned structure is etched away, avoiding the formation of the intersecting point of the dicing blade on the protective layer 130, thus preventing the generation of the cracks in the protective layer 130 and the extension of the cracks.

In the above embodiments, a part of the epitaxial layer 120 is retained when forming the dicing channels 200. The groove 300 penetrates through the protective layer 130 and the epitaxial layer 120 in the depth direction, and extends to the upper surface of the substrate 110. When the dicing blade cuts the upper surface of the protective layer 130, the cracks generated by the explosion point at the bottom of the substrate 110 extend upward to the upper surface (i.e., upper surface) of the substrate 110, completing the splitting of the chiplets. By completely etching away the protective layer and the epitaxial layer at the patterned structure, it is possible to simultaneously avoid the generation of the cracks in the protective layer and the epitaxial layer, fundamentally preventing the extension of the cracks.

In the above embodiments, as illustrated in FIG. 6, the groove 300 is defined on the protective layer 130, and a ratio of a depth h1 of the groove 300 to a thickness h2 of the protective layer 130 is greater than or equal to 1:3. Thinning treatment is performed on the protective layer 130 in the contact area of the dicing blade, at least etching ⅓ of the thickness of the protective layer 130 to define the groove 300. This reduces the risk of large cracks being generated in the protective layer 130 due to its brittleness. Even if fine cracks are generated in the thinner protective layer 130, they are unlikely to continue extending to the epitaxial structure, affecting the performance of the elements. In the embodiment, the upper surface of the dicing channel 200 is still covered by the complete protective layer 130, forming the groove 300 without reducing the protective ability of the protective layer 130 for the side surfaces of the chiplets, avoiding the generation of the cracks at the dicing intersecting point of the dicing blade on the protective layer 130 and preventing the extension of the cracks.

In some embodiments, as illustrated in FIG. 7, the groove 300 penetrates through the protective layer 130 in the depth direction and extends below the surface of the epitaxial layer 120. A ratio of an extension depth h3 of the groove 300 in the epitaxial layer 120 to a thickness h4 of the epitaxial layer 120 is less than or equal to 1:3. Completely removing the protective layer 130 in the region where the patterned structure 400 is located without affecting the structure of the epitaxial layer 120, this etching depth ratio setting can fundamentally eliminate the generation of the cracks in the protective layer 130 within the intersecting area of the dicing channels, and is suitable for the dicing chiplet process with smaller dicing channel widths and higher dicing precision requirements.

In the embodiment, as illustrated in FIGS. 4 to 7, the patterned structure 400 is the groove 300 with cross shape, i.e., the groove 300 is a hollow cross-shaped notch 410. The cross-shaped notch 410 has four orthogonal branches extending along the dicing channels 200, with each branch extending beyond the overlapping area 210 of the dicing channels 200. Each branch is reserved with a certain width d1 from the edge of the dicing channel where this branch is located, and d1≥0.1 μm, providing basic coverage and protection for the side surfaces of the chiplets. After dicing LED, each cross-shaped notch 410 is divided into four L-shaped notches, as illustrated in FIG. 21, four corners of each chiplet are respectively provided with the L-shaped notches.

In an alternative embodiment, in the extension direction of the branch of the cross-shaped structure, 0.1 μm≤d1≤½D, where d1 represents the distance between the branch and the sidewall of the corresponding chiplet, and D is the width of the dicing channel 200. d1≥0.1 μm can provide the most basic protective effect for the side surface of the chiplet.

In an alternative embodiment, the width d2 of the branch of the groove 300 (i.e., the branch of the cross-shaped notch 410) is greater than or equal to 0.1 μm, and less than or equal to ⅔ of the width of the dicing channel, i.e., 0.1 μm≤d2≤⅔D. Setting a larger width for the branch of the cross-shaped notch 410 minimizes the probability of cracks, as well as edge and corner chipping in the protective layer 130.

In an alternative embodiment, 3 μm≤d1≤⅓D. The width of the protective layer with d1≥3 μm can provide comprehensive protection for the side surface of the chiplet, ensuring the quality reliability of elements; at the same time, d1≤⅓D, i.e., the width d2 of the orthogonal branch of the groove 300 is d2≥⅓D. The orthogonal branch width is greater than the scratch width of the dicing blade contacting the protective layer 130, and provides a certain dicing tolerance, ensuring that when the dicing blade splits in the intersecting area of the dicing channels, it falls within the cross-shaped notch 410 of the patterned structure 400, avoiding contact and friction between the dicing blade and the edge of the patterned structure 400 when splitting the chiplets, thereby avoiding the generation of additional cracks at the edges of the cross-shaped notch 410.

### Embodiment 2

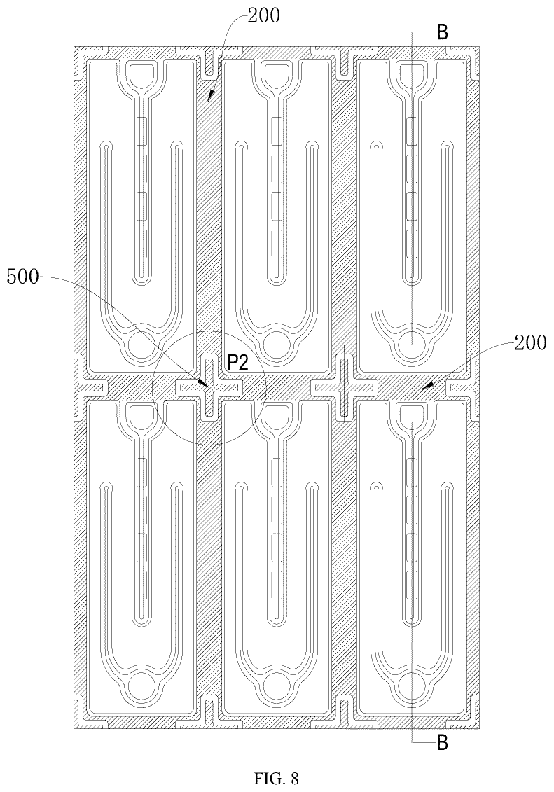

The embodiment provides a LED, as illustrated in FIGS. 8 to 10, the difference from Embodiment 1 is that: the patterned structure 500 is a cross-shaped island, including: a cross-shaped groove 300 and a cross-shaped island body 510.

The cross-shaped groove 300 is located in the intersecting area of the dicing channels, similar in the structure to the patterned structure in Embodiment 1, the cross-shaped groove 300 in this embodiment is also the hollow cross-shaped notch 410.

The cross-shaped island body 510 is located inside the cross-shaped groove 300, a gap 520 is defined between the edge of the cross-shaped island body 510 and the edge of the cross-shaped groove 300. The gap 520 is a groove that extends at least into the protective layer 130 in the depth direction, and is a continuous groove that can isolate the island body 510 from the chiplets and the external dicing channels 200. When the dicing blade repeatedly contacts the protective layer 130, even if the cracks are generated at the intersecting point, the distance that the cracks extend in any direction will be limited to the interior of the island body 510, the cracks are unable to extend to the epitaxial structure to affect the performance of the elements. Additionally, the difference between the cross-shaped island in this embodiment and the cross-shaped notch 410 provided in Embodiment 1 also lies in that the island body 510 retains the original cross-shaped structure in the intersecting area, avoiding the structural loss with large height difference caused by completely etching and hollowing out the entire patterned structure 500, preventing encapsulation defect at the corners of the chiplets during subsequent encapsulation processes, affecting process stability and chip quality.

In an alternative embodiment, the protective layer 130 of the island body 510 is completely retained. After dicing, the island body 510 is divided into four L-shaped corner guards. In some embodiments, as illustrated in FIG. 22, each chiplet is provided with multiple dicing channels 200 including two transverse dicing channels and two longitudinal dicing channels extending respectively along the transverse and longitudinal directions; after dicing, four corners of each chiplet are respectively provided with the L-shaped corner guards. The upper surface of a part of the protective layer 130 at the island body 510 and the upper surface of a part of the protective layer 130 at the dicing channels 200 are at the same height, ensuring the encapsulation quality during the encapsulation process. The widths of the gaps 520 around the island body 510 are the same, the distance d1 between the gap 520 and the edge of the dicing channel is similar in principle to the structural parameters in Embodiment 1. The branches of the island body 510 need to have a certain width, where the width of the branch d3≥1 μm, allowing the dicing blade to fall onto each orthogonal branch of the island body 510 when passing through the intersecting area of the dicing channels 200. After dicing, the island body 510 can be divided into four structurally complete L-shaped corner guards still having a certain width and structural strength, thereby improving the process quality of the subsequent encapsulation.

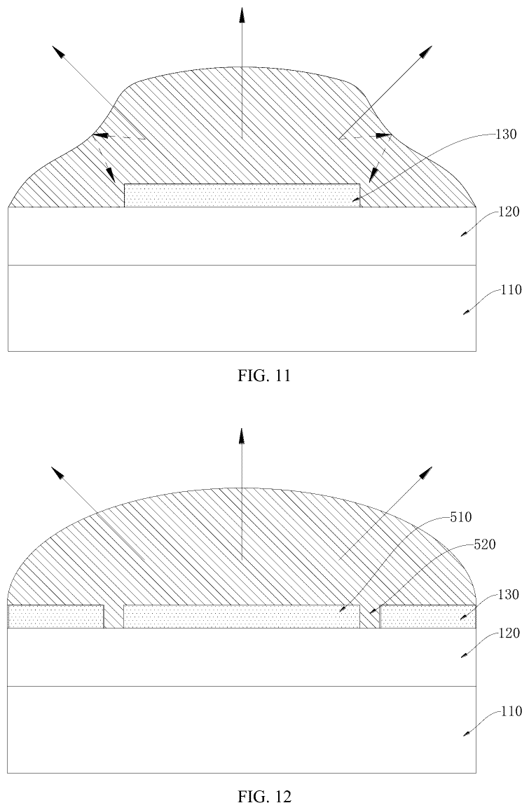

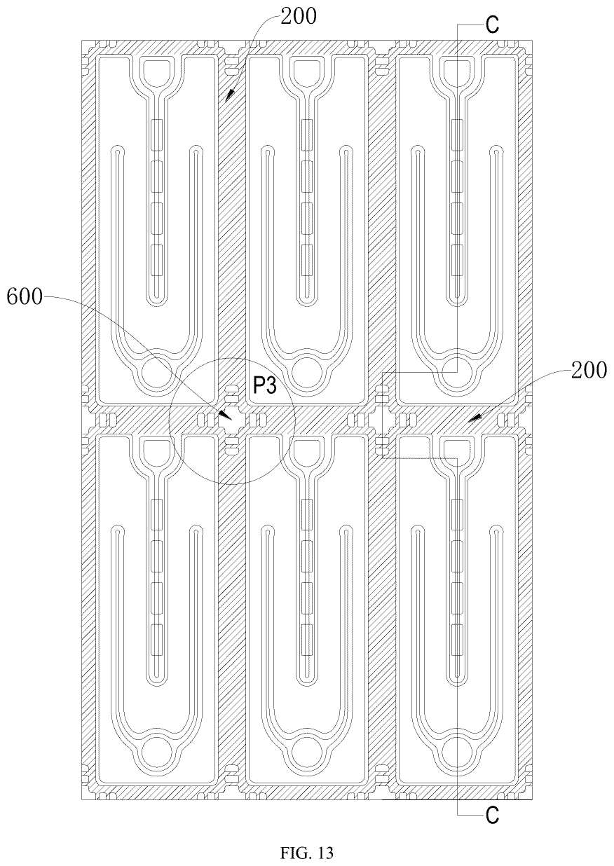

As illustrated in FIGS. 11 and 12, FIG. 11 illustrates a schematic light-emitting diagram of the LED provided by Embodiment 1 with the groove 300 in the patterned structure. Due to the completely hollowed-out groove structure in the intersecting area of the dicing channels of the adjacent chiplets, the bottom of the groove has a significant height difference with the initial plane of the dicing channels 200. During the subsequent encapsulation process, the encapsulant above the groove 300 will adhere to the shape of the groove 300 and partially sink, affecting the uniformity of the encapsulant thickness and making it difficult for the edge of the encapsulant to form a flat light-emitting surface.

The problems arising from this are: On one hand, when the light passes through the edge of the encapsulant, it will be obstructed or refracted, causing the shape and direction of the emitted light to become uneven. Some of the light may be scattered or reflected by the light-emitting surface that is recessed on the two sides of the encapsulant, creating differences in light intensity in different directions, resulting in non-uniform brightness or shape of the emitted light, affecting the focusing degree and light propagation of the LED. On the other hand, during the long-term use of the light-emitting device, the unevenness of the encapsulant thickness and the uneven edges may trigger issues related to product quality reliability. For example, uneven encapsulant thickness can lead to stress concentration, increasing the risk of product cracking, damaging the integrity of the encapsulation and affecting the performance and lifespan of the light-emitting device.

To improve the encapsulation process defects caused by the groove structure provided by Embodiment 1, this embodiment retains the island body 510 in the groove 300 to reduce the impact of the height difference produced by the patterned structure on the encapsulation process.

As illustrated in FIG. 12, it illustrates a schematic light-emitting diagram of the LED provided by Embodiment 2 with the patterned structure including the island body 510 and the gaps 520. The presence of the island body 520 reduces the area of the height difference region between the patterned structure and the initial dicing channels 200, effectively avoiding structural loss with large height difference caused by completely etching and hollowing out the entire patterned structure, making the subsequent encapsulation thickness more uniform, allowing the edge of the encapsulant to form the basically flat light-emitting surface, minimizing the loss of the light-emitting efficiency caused by light reflection at the edges of the light-emitting area, improving the uniformity and consistency of the light-emitting direction, ensuring stable chip processing and chip quality.

### Embodiment 3

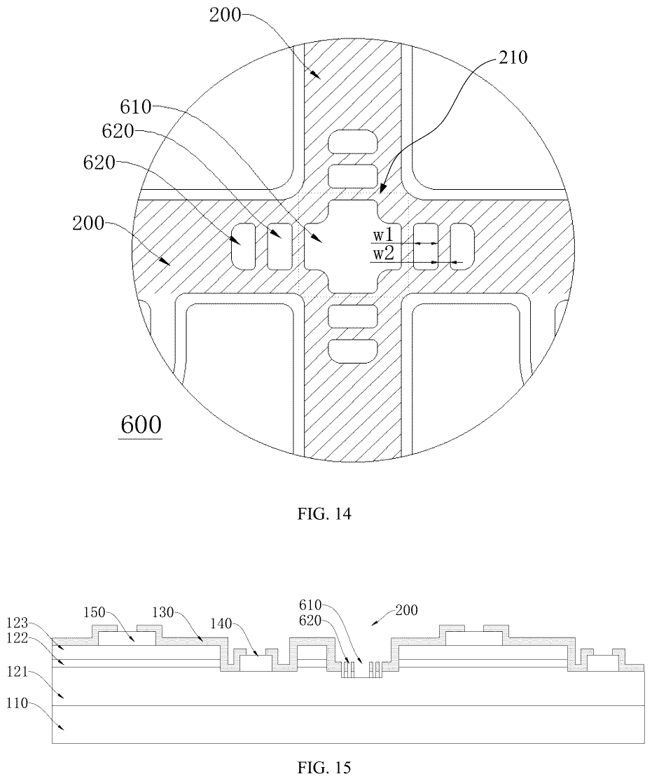

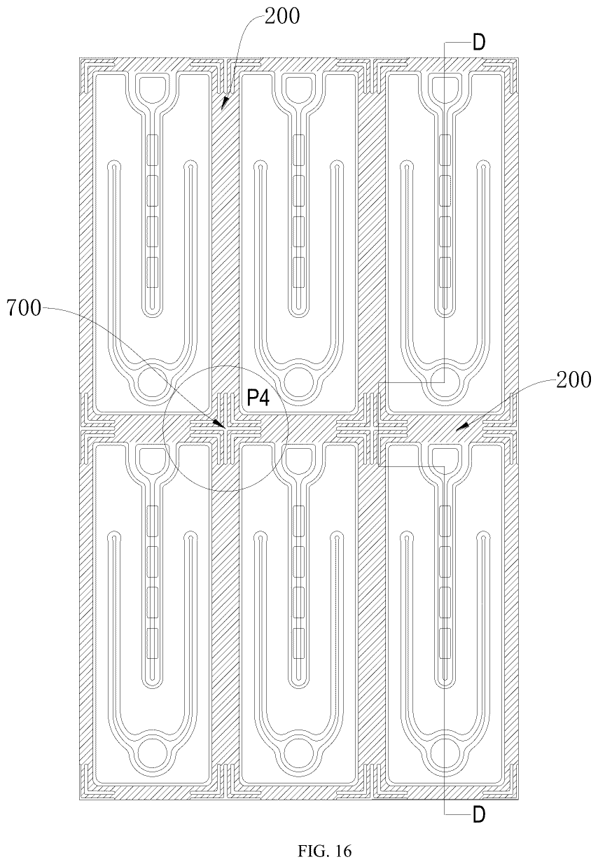

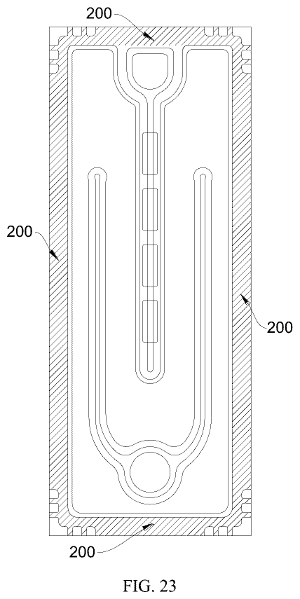

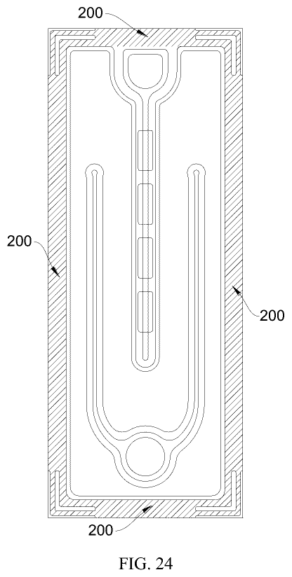

The embodiment provides a LED, as illustrated in FIGS. 13 to 15, the difference from Embodiments 1 and 2 is that: the patterned structure 600 is an array structure. The array structure includes a central notch 610 located in the intersecting area, specifically, the central notch 610 is located inside the overlapping area 210. There are several strip grooves 620 arranged in an array along the extension directions of the dicing channels 200, and an extension direction of each strip groove 620 is perpendicular to the extension direction of the dicing channel 200 where it is located. The central notch 610 inside the overlapping area 210 also serves to avoid the edge and corner chipping caused by repeated dicing of the dicing blade on the protective layer 130. A part of the protective layer 130 is retained at the corners of the central notch 610 facing towards the four corners of the adjacent four chiplets, maintaining a uniform width of the protective layer 130 between the corner of each chiplet and the boundary of the central notch 610, avoiding the generation of stress concentration points at the four corners of the central notch 610. In some embodiments, as illustrated in FIG. 23, each chiplet is provided with multiple dicing channels 200 including two transverse dicing channels and two longitudinal dicing channels extending respectively along the transverse and longitudinal directions; after dicing, each array structure is divided into 4 parts, each corner of each chiplet is provided with a quarter of the array structure.

In an alternative embodiment, the width of the strip groove 620 is w1≥0.1 μm. This width w1 allows the opposing sides of the strip groove 620 to be contacted by the dicing blade separately, and even if damage to the groove structure occurs, it does not directly affect the epitaxial layer on the opposite side. A ratio of the width w1 of the strip groove 620 to the distance w2 between this strip groove and the adjacent strip groove (i.e., the strip groove adjacent to this strip groove) is in a range of 1:6 to 5:1, where the adjacent strip groove refers to the strip groove facing away from the central notch. The setting of the width w1 and the distance w2 follows the principle of proportionality, taking into account both the integrity and continuity of the protective layer 130 coverage inside the dicing channels 200 and the effectiveness of the grooves 300 in blocking the cracks. When the dicing blade comes into contact with the protective layer 130 in the spacing area of the strip grooves 620, the protective layer 130 in the spacing area has sufficient strength to maintain its structural stability, reducing the probability of breakage or crack generation due to contact with the dicing blade; after the cracks are generated, the strip groove 620 with the certain width can prevent the cracks from continuing to extend.

In an alternative embodiment, the arrangement of the strip grooves 620 is an equidistant array, with each strip groove 620 and each spacing area of the strip grooves having the same structural parameters, making the etching process for forming the patterned structure 600 simpler. The arrangement of the strip grooves 620 can also be a non-equidistant array or a gradient array: when using a dense outer and sparse inner arrangement, the ratio of the width w1 of the strip groove 620 to the distance w2 between the strip groove 620 and the adjacent strip groove is in a range of 1:6 to 1:1, such as: 1:6, 1:5, 1:4, 1:3, 1:2, 1:1, etc. The overall coverage area of the protective layer 130 is larger, providing stronger protection for the chiplets; when using a sparse outer and dense inner arrangement, the size ratio of the width w1 of the strip groove 620 to the distance w2 between the adjacent grooves is in range of 1:1 to 5:1, such as: 1:1, 2:1, 3:1, 4:1, 5:1, etc. The overall coverage area of the protective layer 130 is relatively reduced, weakening the protection for the chiplets to a certain extent, but also lowering the probability of chipping of the protective layer 130, and the larger overall groove area makes the patterned structure 600 easier to be identified by dicing equipment such as laser splitting machines and dicing machines, improving the dicing alignment accuracy.

### Embodiment 4

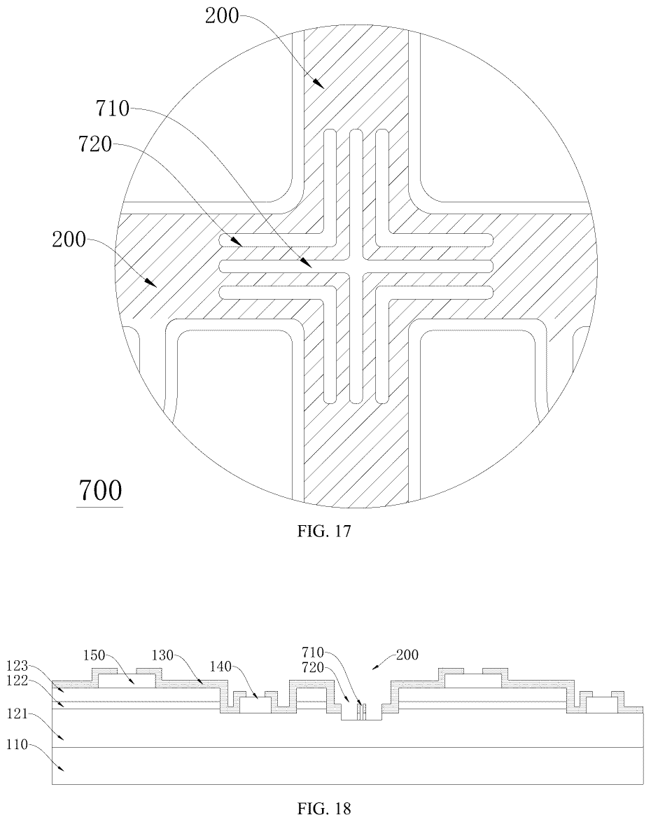

The embodiment provides a LED, as illustrated in FIGS. 16 to 18, the difference from Embodiments 1 to 3 is that: in this embodiment, the patterned structure 700 is an array structure, including: a cross-shaped slot 710 and multiple linear slots.

The cross-shaped slot 710 is located in the intersecting area of the dicing channels 200. The cross-shaped slot 710 includes transverse and longitudinal branches extending respectively in the transverse and longitudinal directions. The cross-shaped slot 710 located in the intersecting area directly avoids the generation of the repeated contact points of the dicing blade on the protective layer 130, and even under conditions of dicing accuracy errors, the dicing blade generates cracks when contacting the protective layer 130 in the intersecting area of the dicing channels 200, it can prevent the cracks from continuing to extend. In some embodiments, as illustrated in FIG. 24, each chiplet is provided with multiple dicing channels 200 including two transverse dicing channels and two longitudinal dicing channels extending respectively along the transverse and longitudinal directions; after dicing, each array structure is divided into 4 parts, each corner of each chiplet is provided with a quarter of the array structure.

The linear slots include transverse linear slots and longitudinal linear slots. The transverse linear slots are distributed within the dicing channels 200 with the transverse branch of the cross-shaped slot as a symmetry axis, and the longitudinal linear slots are distributed within the dicing channels 200 with the longitudinal branch of the cross-shaped slot as a symmetry axis. The linear slots can play a role in multiple blocking of crack extension, protecting the structure and performance of the chiplets.

In an alternative embodiment, the linear slots in the two dicing channels 200 of the transverse and longitudinal sidewalls of the chiplet are connected to form an L-shaped slot 720, which can provide protective effects for the corner of the adjacent sides of the chiplet. Cracks generated during the dicing process are blocked by the L-shaped slot 720 and cannot extend to the epitaxial structure of the chiplet. The L-shaped slot 720 can be arranged in multiple groups along diagonal directions of the intersecting area of the dicing channels, with the multiple group of L-shaped slots 720 providing better blocking effects against the extension of cracks; at the same time, the upper surface of the protective layer 130 retained between the multiple group of L-shaped slots 720 and the upper surface of the protective layer 130 of the dicing channels 200 are at the same height, similar to the principle of the cross-shaped island structure, it can also avoid significant structural loss with large height differences caused by completely etching and hollowing out the entire patterned structure 700, preventing encapsulation defects at the corners of the chiplets during subsequent encapsulation processes, affecting process stability and chip quality.

In the LEDs provided by the multiple embodiments of the disclosure, each patterned structure is simultaneously configured as a dicing mark that can be identified by dicing equipment. Both the laser splitting machine and the dicing machine can identify the dicing mark to precisely locate the dicing position, overcoming technical defects in the related art of dicing position identification by capturing chiplet patterns, such as difficulties in capturing complete chiplet patterns or inability to capture different chiplet patterns on the same wafer. By identifying the patterned structure in the intersecting area of the dicing channels, the dicing position accuracy of the four corners of each chiplet is improved, preventing dicing offset, reducing the number of alarm shutdowns of the machine, and ensuring the stability of the dicing process.

### Embodiment 5

The embodiment provides a LED, referring continuously to FIGS. 8 to 10, the LED includes: a substrate 110, an epitaxial layer 120 and a protective layer 130. The substrate 110 has a upper surface and a lower surface disposed opposite to the upper surface, the epitaxial layer 120 is disposed the substrate 110, the epitaxial layer 120 includes a first semiconductor layer 121, an active layer 122, and a second semiconductor layer 123 stacked sequentially in that order, and the protective layer 130 covers the epitaxial layer 120. The epitaxial layer 120 is divided into multiple chiplets, the chiplets include transverse sidewalls and longitudinal sidewalls intersecting in the transverse and longitudinal directions, dicing channels 200 are defined between the adjacent chiplets, the dicing channels 200 include transverse dicing channels and longitudinal dicing channels extending respectively in the transverse and longitudinal directions, the protective layer 130 covers the dicing channels 200 and the sidewalls of the chiplets, and a groove 300 extending toward the substrate 110 is defined in the protective layer 130 of an intersecting area of the transverse dicing channel and the longitudinal dicing channel. The groove 300 can prevent the cracks generated by the repeated contact of the dicing blade with the protective layer 130 from continuing to extend to the epitaxial structure. An island body 510 is disposed inside the groove 300, with a gap 520 between the island body 510 and the edge of the groove 300.

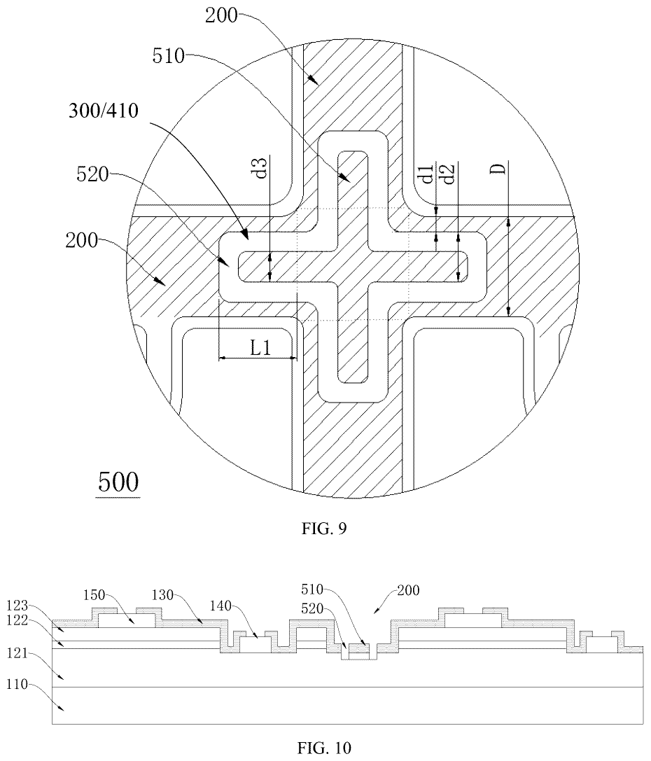

In an alternative embodiment, as illustrated in FIG. 9, the groove 300 and the island body 510 have branches in both the transverse dicing channels and the longitudinal dicing channels. The branches of the groove 300 and the branches of the island body 510 intersect, together forming a cross-shaped island structure.

In an alternative embodiment, the widths of the gaps 520 around the island body 510 are the same, the edge of the gap 520 parallel to the dicing channel 200 where the gap 520 is located has a width distance d1 from the edge of this dicing channel 200, where d1≥0.1 μm, it is able to provide basic coverage and protection for the side surfaces of the chiplets, and this width distance can minimize the probability of cracks and chipping in the protective layer 130.

In an alternative embodiment, 3 μm≤d1≤⅓D, where D is the width of the dicing channel 200. A protective layer width with d1≥3 μm can provide comprehensive protection for the side surfaces of the chiplets, ensuring the reliability of element quality; at the same time, d1≤⅓D, i.e., the orthogonal branch width d2 of the groove 300 is d2≥⅓D. The orthogonal branch width is greater than the scratch width of the dicing blade contacting the protective layer 130, which provides a certain dicing tolerance, ensuring that when the dicing blade cuts in the intersecting area of the dicing channels, it falls within the overall structure of the island, avoiding contact and friction between the dicing blade and the edge of the groove 300 when dicing the chiplets, leading to more cracks at the edges of the dicing channels 200 and extending.

Each branch of the cross-shaped island body 510 extends to the dicing channel 200 of the adjacent chiplets. Defining the rectangular area where the transverse dicing channel and the longitudinal dicing channel overlap as the overlapping area, that is, each branch of the island body 510 extends beyond the overlapping area of the dicing channels 200. It can be understood that if the island body 510 is only limited to the interior of the overlapping area of the dicing channels 200, there is still a probability and uncertainty that cracks will extend along the protective layer 130 to all sides during dicing, especially making it difficult to effectively protect the corners of the chiplets. Extending the four branches of the island body 510 into the intersecting dicing channels 200 for a certain distance is equivalent to removing more of the protective layer 130 along the extension directions of the dicing channels 200, i.e., performing a larger area hollowing treatment on the dicing channels 200. On one hand, the area of the remaining protective layer 130 can effectively lower the probability of the protective layer 130 creaking during dicing. On the other hand, since the groove 300 has a similar shape to the island body 510, the groove 300 also extends beyond the overlapping area, and the groove 300 extending outward plays a blocking role against the extension of cracks to the corners of the chiplets. Even if the cracks are generated at the intersecting point between the dicing channels 200 and the protective layer 130, it is difficult for them to continue to extend, so as to avoid edge and corner chipping phenomena.

In an alternative embodiment, defining that each branch of the groove 300 has a length in the extension direction and the width in the direction intersecting with the extension direction, the extension distance L1 of each branch of the groove 300 outside the overlapping area is greater than or equal to 0.1 μm, and less than or equal to half the length of the sidewall of the corresponding chiplet in the length direction. The extension distance L1 is at least 0.1 μm to form a dislocation between the starting points of the cracks and the corners of the chiplets, while the maximum extension distance L1 is half the length of the sidewall of the corresponding chiplet, leaving some of the protective layer 130 in the x-axis and y-axis dicing channels 200, ensuring good protection of the side surface of the chiplets.

In an alternative embodiment, the extension distance L1 of each branch of the groove 300 outside the overlapping area is greater than or equal to 3 μm, and less than or equal to one quarter of the length of the sidewall of the corresponding chiplet in the length direction. This size limitation optimizes the parameter selection range between the protection effect on the side surfaces of the chiplets and the location where the crack are generated. Compared with the aforementioned embodiment, setting the extension distance L1 to at least 3 μm further increases the dislocation between the starting points of the cracks and the corners of the chiplets, making the contact points between the dicing blade and the boundaries of the protective layer 130 as far away from the four corners of the chiplets as possible. At the same time, the extension distance L1 being less than or equal to one quarter of the length of the sidewall of the corresponding chiplet in the length direction leaves enough area of the protective layer 130 remaining in both the transverse and longitudinal directions of the dicing channels 200, providing better protection for the side surfaces of the chiplets.

Similar to the principle of structural parameter settings in Embodiment 1. The branches of the island body 510 need to have a certain width, the branch width d3≥1 μm, allowing the dicing blade to fall onto each orthogonal branch of the island body 510 when passing through the intersecting area of the dicing channels 200. After dicing, the island body 510 can be divided into four structurally complete L-shaped corner guards still having a certain width and structural strength, thereby improving the quality of the subsequent encapsulation process.

In some embodiments, the lengths of the four branches of the groove 300 and the lengths of the four branches of the island body 510 are the same or different. FIG. 9 only illustrates the case where the four branches have the same length. It can be understood that the lengths of the four branches of the island structure can also be adjusted according to the dimensions and aspect ratios of the chiplets themselves, balancing and optimizing the protective effects on two sides of the chiplets in the length and width directions.

In an alternative embodiment, the protective layer 130 of the island body 510 is completely retained. After dicing, the island body 510 is divided into four L-shaped corner guards. The protective layer 130 at the island body 510 and the protective layer 130 at the dicing channels 200 are at the same height, ensuring the quality of the encapsulation process.

In the above embodiments, the depth of the groove 300 is greater than or equal to 0.01 μm. This groove depth is specified as the minimum depth capable of isolating the cracks generated at the intersecting point.

In the above embodiments, the groove 300 extends in the depth direction into the protective layer 130 and at most penetrates through the protective layer 130. When forming the dicing channels 200, the entire epitaxial layer 120 at the dicing channels 200 is etched away. In the depth direction, only the substrate 110 and the protective layer 130 are retained at the dicing channels 200. By forming the structure of the groove 300 and the island body 510 on the protective layer 130, even if the cracks are generated in the protective layer 130, they cannot extend downward to the epitaxial layer 120, effectively preventing edge and corner chipping. The structure of the groove 300 and the island body 510 can also prevent solder paste from entering during die bonding and causing electrical leakage. It can be understood that the aforementioned embodiments are also applicable when only a part of the epitaxial layer 120 at the dicing channels 200 is etched away when forming the dicing channels 200.

In the above embodiments, a part of the epitaxial layer 120 is retained when forming the dicing channels 200. The groove 300 penetrates through the protective layer 130 in the depth direction and extends below the upper surface of the epitaxial layer 120. The protective layer 130 at the cross-shaped island structure is completely etched away to avoid the intersecting point of the dicing blade forming on the protective layer 130, thus preventing the generation of the cracks in the protective layer 130 and the extension of the cracks.

In the above embodiments, a part of the epitaxial layer 120 is retained when forming the dicing channels 200. The groove 300 penetrates through the protective layer 130 and the epitaxial layer 120 in the depth direction, and extends to the upper surface of the substrate 110. When the dicing blade dices the upper surface of the protective layer 130, the cracks generated by the explosion point at the bottom of the substrate 110 extend upward to the upper surface of the substrate 110, completing the splitting of the chiplets.

In the above embodiments, the groove 300 is defined on the protective layer 130, and a ratio of the depth h1 of the groove 300 to the thickness h2 of the protective layer 130 is greater than or equal to 1:3. Thinning treatment is performed on the protective layer 130 in the contact area of the dicing blade, at least etching ⅓ of the thickness of the protective layer 130 to define the groove 300. This reduces the risk of large cracks being generated in the protective layer 130 due to its brittleness. Even if fine cracks are generated in the thinner protective layer 130, they are difficult to continue extending to the epitaxial structure and affect element performance. In the embodiment, the upper surface of the dicing channels 200 is still covered by the complete protective layer 130, forming the groove 300 without reducing the protective ability of the protective layer 130 for the side surfaces of the chiplets, avoiding the generation of the cracks at the dicing intersecting point of the dicing blade on the protective layer 130 and preventing the extension of the cracks.

In the above multiple embodiments, the groove 300 penetrates through the protective layer 130 and extends below the surface of the epitaxial layer 120 in the depth direction, with the ratio of the extension depth h3 of the groove 300 in the epitaxial layer 120 to the thickness h4 of the epitaxial layer 120 being less than or equal to 1:3. The protective layer 130 in the region where the island structure is located is completely removed without affecting the structure of the epitaxial layer 120. This etching depth ratio can fundamentally eliminate the generation of the cracks in the protective layer 130 within the intersecting area of the dicing channels, and is suitable for the chiplet dicing process with smaller dicing channel widths and higher dicing accuracy requirements.

When the dicing blade repeatedly contacts the protective layer, even if cracking occurs at the intersecting point, the distance that the cracks extend in any direction is limited to the interior of the island body 510, the cracks are unable to extend to the epitaxial structure to adversely affect the element performance. By setting the island body 510 in the groove 300, it can also reduce the overall coverage area of the groove 300, avoiding the height difference and structural deficiency caused by completely etching and hollowing out the entire groove 300. During the subsequent encapsulation process, the thickness of the encapsulant is more uniform, and the edge of the encapsulant can form a basically flat light-emitting surface, reducing the loss of light-emitting efficiency caused by light reflection at the edges of the light-emitting area, improving the light-emitting uniformity and the consistency of the light-emitting direction, and stabilizing the quality of the chiplets.

### Embodiment 6

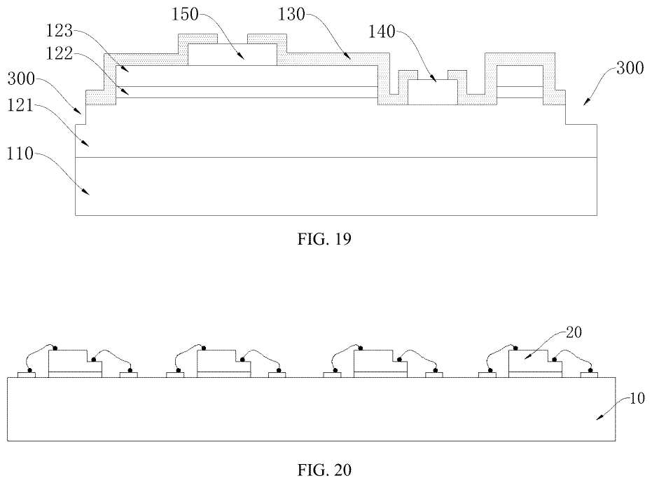

The disclosure also provides a LED chiplet, obtained by dicing the LED from anyone of the embodiments of the disclosure. As illustrated in FIG. 19, taking the LED provided in Embodiment 1 as an example, the aforementioned chiplet includes a substrate 110, an epitaxial layer 120, and a protective layer 130. The substrate 110 has a upper surface and a lower surface that are oppositely arranged, the epitaxial layer 120 is disposed on the substrate 110, the epitaxial layer 120 includes a first semiconductor layer 121, an active layer 122, and a second semiconductor layer 123 stacked sequentially in that order. The protective layer 130 covers the epitaxial layer 120. In an alternative embodiment, the aforementioned chiplet further includes an electrode structure, the electrode structure includes a first electrode 140 and a second electrode 150 respectively electrically connected to the first semiconductor layer 121 and the second semiconductor layer 123. The material of the electrode structure is selected from at least one selected from the group consisting of gold, silver, copper, aluminum, chromium, nickel, titanium, and platinum, or at least one of alloys and stacked layers composed of the aforementioned materials.

Since the patterned structure is disposed in the intersecting area of the dicing channels between every four adjacent chiplets on the LED wafer, each patterned structure can play a protective role for the epitaxial structures at the corners of the four adjacent chiplets. The patterned structure restricts the cracks generated at the intersecting point within the patterned structure itself, effectively isolating adjacent chiplets and preventing the cracks from extending along the protective layer 130 to the corners of the adjacent chiplets. The groove 300 of the patterned structure divides the four adjacent chips into four relatively independent partitions, preventing the cracks from continuing to extend to the epitaxial structures of the adjacent chiplets through the groove 300. The epitaxial structure of the single LED chiplet obtained by dicing the patterned structure does not have cracks, the transverse sidewall and the longitudinal sidewall of the LED chiplet remain flush, and the quality reliability is ensured.

### Embodiment 7

The disclosure also provides a light-emitting device, as illustrated in FIG. 20, the light-emitting device includes a circuit board 10 and a light-emitting element 20 disposed on the circuit board 10, the light-emitting element 20 can be the LED chiplet provided in the above embodiment of the disclosure. The epitaxial structure of the aforementioned LED chiplet has no cracks, the transverse sidewall and the longitudinal sidewall of the LED chiplet remain flush, and the quality reliability is ensured; and the LED chiplet has good light-emitting efficiency, thus the light-emitting device also has good light-emitting effect.

What is claimed is:

1. A light-emitting diode (LED), comprising:
a substrate, having a upper surface and a lower surface disposed opposite to the upper surface;
an epitaxial layer, disposed on the upper surface of the substrate, wherein the epitaxial layer comprises: a first semiconductor layer, an active layer, and a second semiconductor layer which are sequentially stacked in that order; and
a protective layer, covering the epitaxial layer;
wherein the epitaxial layer is divided into a plurality of chiplets, each chiplet comprises: sidewalls intersecting in transverse and longitudinal directions, and the sidewalls of each chiplet comprise: transverse sidewalls and longitudinal sidewalls; every adjacent two of the plurality of chiplets define a dicing channel, and the dicing channels of the plurality of chiplets comprise transverse dicing channels and longitudinal dicing channels extending respectively in the transverse and longitudinal directions; and the protective layer covers the dicing channels of the plurality of chiplets and the sidewalls of the plurality of chiplets, the protective layer is provided with a patterned structure in each intersecting area of the transverse dicing channels and the longitudinal dicing channels, and the patterned structure comprises a groove extending toward the substrate.

2. The LED as claimed in claim 1, wherein the patterned structure comprises a cross-shaped structure intersecting in the transverse and longitudinal directions, and each branch of the cross-shaped structure extends to a corresponding one of the dicing channels of the plurality of chiplets.

3. The LED as claimed in claim 2, wherein each branch of the cross-shaped structure has a length in an extension direction and a width in a direction intersecting the extension direction, an extension length of each branch outside an overlapping area of the dicing channels is greater than or equal to 0.1 μm, and less than or equal to ½ of a length of a sidewall of a corresponding one of the plurality of chiplets in a length direction.

4. The LED as claimed in claim 3, wherein the width of each branch is greater than or equal to 0.1 μm, and less than or equal to ⅔ of a width of the corresponding dicing channel.

5. The LED as claimed in claim 2, wherein in an extension direction of each branch of the cross-shaped structure, a distance between each branch of the cross-shaped structure and a sidewall of a corresponding one of the plurality of chiplets is greater than or equal to 0.1 μm, and less than or equal to ½ of a width of the corresponding dicing channel; and four branches of the cross-shaped structure have a same length or different lengths.

6. The LED as claimed in claim 1, wherein the groove extends into the protective layer along a depth direction, and at most penetrates through the protective layer.

7. The LED as claimed in claim 1, wherein the groove extends through the protective layer along a depth direction, and extends to below an upper surface of the epitaxial layer.

8. The LED as claimed in claim 1, wherein the groove extends through the protective layer and the epitaxial layer along a depth direction, and extends to the upper surface of the substrate.

9. The LED as claimed in claim 1, wherein a depth of the groove is greater than or equal to 0.01 μm; and a ratio of the depth of the groove to a thickness of the protective layer is greater than or equal to 1:3.

10. The LED as claimed in claim 2, wherein the cross-shaped structure forms a cross-shaped island, and the cross-shaped island comprises:
a cross-shaped groove located at the intersecting area of the dicing channels, and
a cross-shaped island body located inside the cross-shaped groove; wherein an edge of the cross-shaped island body and an edge of the cross-shaped groove define a gap.

11. The LED as claimed in claim 10, wherein an upper surface of a part of the protective layer located at the cross-shaped island and an upper surface of a part of the protective layer located at the dicing channels are at a same height.

12. The LED as claimed in claim 1, wherein the patterned structure is an array structure, and the array structure comprises:
a central notch located at the intersecting area, and
a plurality of strip grooves arranged in an array along extension directions of the dicing channels from the central notch; wherein an extension direction of each strip groove is perpendicular to the extension direction of one of the dicing channels where the strip groove is located.

13. The LED as claimed in claim 12, wherein a width of each strip groove is greater than or equal to 0.1 μm.

14. The LED as claimed in claim 12, wherein a ratio of the width of each strip groove to a distance between the strip groove and an adjacent strip groove of the plurality of strip groove is in a range of 1:6 to 5:1, and the adjacent strip groove is one of the plurality of strip grooves facing away from the central notch.

15. The LED as claimed in claim 12, wherein an arrangement of the plurality of strip grooves is an equidistant array or a non-equidistant array.

16. The LED as claimed in claim 1, wherein the patterned structure is an array structure, and the array structure comprises:
a cross-shaped slot located at the intersecting area; wherein the cross-shaped slot comprise: a transverse branch and a longitudinal branch extending respectively in the transverse and longitudinal directions; and
a plurality of linear slots, comprising: transverse linear slots and longitudinal linear slots; wherein the transverse linear slots are distributed within the dicing channels with the transverse branch of the cross-shaped slot as a symmetry axis, and the longitudinal linear slots are distributed within the dicing channels with the longitudinal branch of the cross-shaped slot as a symmetry axis.

17. The LED as claimed in claim 16, wherein the linear slots in two of the dicing channels respectively adjacent to the transverse sidewall and the longitudinal sidewall of a corresponding one of the plurality of chiplets are connected to define a L-shaped slot.

18. The LED as claimed in claim 1, wherein the patterned structure is configured as a dicing mark capable of being identified by dicing equipment.

19. A LED chiplet, obtained by dicing the LED as claimed in claim 1.

20. A light-emitting device, comprising: a substrate and a light-emitting element fixed on the substrate; wherein the light-emitting element comprises at least one LED chiplet as claimed in claim 19.
